(19) United States
(12) Patent Application Publication
(10) Pub. No.: US 2009/0200563 A1
(43) Pub. Date: Aug. 13, 2009

(54) Group III nitride semiconductor light-emitting device and production method therefor

(75) Inventors: Koichi Goshonoo, Aichi (JP); Miki Moriyama, Aichi (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: TOYODA GOSEI CO., LTD., Aichi-ken (JP)

(21) Appl. No.: 12/320,980

(22) Filed: Feb. 10, 2009

(30) Foreign Application Priority Data
Feb. 13, 2008 (JP) 2008-032219
Dec. 26, 2008 (JP) 2008-333496

(51) Int. Cl. H01L 33/00

(52) U.S. Cl. 257/88; 438/43; 257/E33.005

(57) ABSTRACT

Provided is a method for producing a Group III nitride semiconductor light-emitting device including a GaN substrate serving as a growth substrate, which method facilitates tapering of a bottom portion of the GaN substrate. In the production method, firstly, a Group III nitride semiconductor layer, an ITO electrode, a p-electrode, and an n-electrode are formed on the top surface of a GaN substrate through MOCVD. Thereafter, the GaN substrate is thinned through mechanical polishing of the bottom surface thereof, and then scratches formed by mechanical polishing are removed through chemical mechanical polishing, to thereby planarize the bottom surface. Subsequently, a mask is formed on the bottom surface of the GaN substrate, followed by wet etching with phosphoric acid. By virtue of anisotropy in etching of GaN with phosphoric acid, a tapered surface is exposed so as to be inclined by about 60° with respect to the GaN substrate.

### BACKGROUND OF THE INVENTION

1. Field of the Invention

The present invention relates to a Group III nitride semiconductor light-emitting device including a growth substrate formed from a Group III nitride semiconductor (hereinafter may be referred to as “Group III nitride semiconductor growth substrate”), and to a method for producing the light-emitting device. More particularly, the present invention relates to a light-emitting device exhibiting improved light extraction performance, and to a method for producing the light-emitting device.

2. Background Art

Hitherto, there has been known a Group III nitride semiconductor light-emitting devices having a GaN growth substrate, in which the bottom portion of the GaN substrate is processed to have a tapered form for improving the light extraction performance of the light-emitting device (see Japanese Patent Application Laid-Open (kokai) Nos. H11-317546, 2003-086838, and 2005-302804).

Such a bottom-tapered GaN substrate is formed through a machining process such as polishing or dicing. In a method disclosed in Japanese Patent Application Laid-Open (kokai) No. 2005-302804, a damaged layer formed by such a machining process is removed through dry etching, since the damaged layer reduces light extraction performance.

However, the method disclosed in Japanese Patent Application Laid-Open (kokai) No. 2005-302804 poses a problem in terms of ease of processing, since the method requires two steps (machining and dry etching) for forming a bottom-tapered GaN substrate. Meanwhile, when a tapered substrate is formed through a machining process such as dicing, poor reproducibility in tapering may cause variation in brightness or light distribution.

### SUMMARY OF THE INVENTION

In view of the foregoing, an object of the present invention is to provide a method for producing a Group III nitride semiconductor light-emitting device, which method facilitates tapering of a bottom portion of a growth substrate at high reproducibility. Another object of the present invention is to provide a Group III nitride semiconductor light-emitting device including a bottom-tapered growth substrate.

In a first aspect of the present invention, there is provided a method for producing a light-emitting device comprising:

planarizing the bottom surface of the growth substrate;

subsequently, forming a mask having a predetermined pattern on the bottom surface of the growth substrate; and

wet-etching the bottom surface of the growth substrate, to thereby form an embossment including a portion of the bottom surface of the growth substrate, the portion being a planar surface, and a tapered surface which extends from the periphery of the planar surface and are inclined with respect to the growth substrate.

As used herein, “Group III nitride semiconductor” refers to a semiconductor represented by the formula AlₓGa_{y}In_{1-x-y}N (0≦×≦1, 0≦x+y≦1, 0≦x+y≦1), such as GaN, AlGaN, InGaN, or AlGaInN. The n-type impurity employed may be, for example, Si, and the p-type impurity employed may be, for example, Mg.

Examples of known etchants which can be employed for wet etching of a Group III nitride semiconductor include phosphoric acids such as phosphoric acid and pyrophosphoric acid; mixed acid of phosphoric acid and sulfuric acid; potassium hydroxide; and sodium hydroxide. Wet etching of a Group III nitride semiconductor may be carried under irradiation of the semiconductor with a UV ray, or under application of bias to the semiconductor.

The growth substrate employed may be a substrate whose main surface has a predetermined crystal orientation, such as a C-plane substrate, an R-plane substrate, an M-plane substrate, or an A-plane substrate. Generally, a C-plane substrate is employed, since, for example, it is readily available. When a C-plane growth substrate is employed, preferably, the bottom surface of the substrate is an N-polar surface. This is because, as compared with an N-polar surface, a Ga-polar surface is less likely to be etched.

In the first aspect of the present invention, the term “planarizing” refers not only to a step of reducing irregularities on the bottom surface of the growth substrate, but also to a step of treating the bottom surface through removal of a damaged layer formed by, for example, mechanical polishing so that surface irregularities (e.g., scratches) do not develop through wet etching. Such a planarizing step may be carried out through, for example, chemical mechanical polishing or high-temperature thermal treatment after dry etching of the entire bottom surface. Since such a planarizing step is important from the viewpoint of processing accuracy of the bottom surface of the substrate, this step must be carried out before wet etching.

Processing of the bottom surface of the growth substrate may be carried out through combination of wet etching and dry etching. Preferably, the growth substrate is thinned through mechanical polishing before planarizing, for facilitation of subsequent chip separation.

The mask employed for wet etching may be removed or left in place after wet etching.

In the present invention, processing of the bottom surface of the growth substrate (including at least planarizing, or both planarizing and wet etching) may be carried out before or after formation of a semiconductor layer on the top surface of the growth substrate. When processing of the bottom surface of the growth substrate is carried out before formation of a semiconductor layer, planarizing may be performed by dry etching of the entire bottom surface, followed by high-temperature thermal treatment.

A second aspect of the present invention is drawn to a specific embodiment of the method for producing a light-emitting device as described in the first aspect, wherein the bottom surface of the growth substrate is planarized through chemical mechanical polishing.

A third aspect of the present invention is drawn to a specific embodiment of the method for producing a light-emitting device as described in the first or second aspect, wherein wet etching is carried out to a depth of 5 μm or more as measured from the bottom surface of the growth substrate.

When the etching depth is 5 μm or more, light extraction performance is further improved. When a portion which has been thinned through etching corresponds to a chip separation region, chip separation is more readily carried out, which is preferred. The etching depth is more preferably 10 μm or more, much more preferably 50 μm or more.

A fourth aspect of the present invention is drawn to a specific embodiment of the method for producing a light-emitting device as described in the first or second aspect, wherein wet etching is carried out to a depth which is 40 to 70% of the thickness of the growth substrate.

When the etching depth is 40 to 70% of the thickness of the growth substrate, light extraction performance is further improved. When a portion which has been thinned through etching corresponds to a chip separation region, chip separation is more readily carried out, which is preferred. The etching depth is more preferably 45 to 70% of the thickness of the growth substrate, much more preferably 50 to 70% of the thickness of the growth substrate.

A fifth aspect of the present invention is drawn to a specific embodiment of the method for producing a light-emitting device as described in any one of the first to fourth aspects, wherein the tapered surface is inclined by 20° to 70° with respect to the growth substrate.

When the angle of the tapered surface with respect to the growth substrate falls within the above range, light extraction performance is further improved, which is preferred.

A sixth aspect of the present invention is drawn to a specific embodiment of the method for producing a light-emitting device as described in any one of the first to fourth aspects, wherein the tapered surface is inclined by 60° with respect to the growth substrate.

As used herein, “60°” refers not to 60° strictly, but to an angle of 60°±5°.

A seventh aspect of the present invention is drawn to a specific embodiment of the method for producing a light-emitting device as described in any one of the first to sixth aspects, wherein wet etching is carried out by use of phosphoric acid.

Wet etching of a Group III nitride semiconductor with phosphoric acid occurs anisotropically, and the thus-etched semiconductor has a tapered surface inclined by about 60° with respect to C-plane. The temperature of phosphoric acid employed is preferably 100 to 200° C. This is because, when the phosphoric acid temperature is 100° C. or lower, etching rate is reduced (i.e., etching requires a long period of time), whereas when the phosphoric acid temperature is 200° C. or higher, the mask may be damaged. The phosphoric acid temperature is more preferably 140 to 170° C. The phosphoric acid concentration is preferably 1% or more. This is because, when the phosphoric acid concentration is less than 1%, etching rate is reduced. The phosphoric acid concentration is more preferably 10% or more.

An eighth aspect of the present invention is drawn to a specific embodiment of the method for producing a light-emitting device as described in any one of the first to seventh aspects, wherein the growth substrate is a C-plane substrate, and the bottom surface of the growth substrate is an N-polar surface.

A ninth aspect of the present invention is drawn to a specific embodiment of the method for producing a light-emitting device as described in any one of the first to eighth aspects, wherein the growth substrate is a GaN substrate.

A tenth aspect of the present invention is drawn to a specific embodiment of the method for producing a light-emitting device as described in any one of the first to ninth aspects, wherein the embossment comprises one or more protrusions.

An eleventh aspect of the present invention is drawn to a specific embodiment of the method for producing a light-emitting device as described in any one of the first to ninth aspects, wherein the embossment comprises one dent provided at the center of the bottom surface of the growth substrate.

A twelfth aspect of the present invention is drawn to a specific embodiment of the method for producing a light-emitting device as described in any one of the first to eleventh aspects, wherein the embossment has a bottom surface which is parallel to the bottom surface of the growth substrate.

A thirteenth aspect of the present invention is drawn to a specific embodiment of the method for producing a light-emitting device as described in any one of the first to twelfth aspects, wherein the embossment comprises a plurality of protrusions, and a first trench between adjacent protrusions is formed through wet etching which is allowed to proceed until etching eventually stops, so that the trench assumes a V-shape as viewed in a cross section perpendicular to the bottom surface of the growth substrate.

When a first trench is formed through wet etching so that the trench assumes a V-shape as viewed in a cross section perpendicular to the bottom surface of the growth substrate, etching automatically stops when formation of the V-shaped trench has been completed. Therefore, the depth of the first trench can be controlled by determining the size of the corresponding opening of the mask. Thus, there can be produced devices having first trenches of uniform depth; i.e., devices exhibiting uniform performance.

A fourteenth aspect of the present invention is drawn to a specific embodiment of the method for producing a light-emitting device as described in the thirteenth aspect, wherein the depth of first trenches is varied by modifying the size of a plurality of first openings provided in the mask for forming the first trenches.

When the size of the openings of the mask is tuned to a predetermined value, and wet etching is allowed to proceed until etching eventually stops, the depth profile of the first trenches can be controlled to a desired one. Thus, devices exhibiting uniform emission output can be produced.

A fifteenth aspect of the present invention is drawn to a specific embodiment of the method for producing a light-emitting device as described in any one of the first to fourteenth aspects, wherein the embossment comprises a plurality of protrusions; and both the first trench, which is provided between adjacent protrusions and assumes a V-shape as viewed in a cross section perpendicular to the bottom surface of the growth substrate, and a second trench which has a depth greater than that of the first trench and is employed for separating the light-emitting device into chips are formed through single-step wet etching via a first opening provided in the mask for forming the first trench and a second opening provided in the mask for forming the second trench, the second opening being greater in size than the first opening.

Thus, the first trench and the second trench, which has a depth greater than that of the first trench and is employed for separating the device into chips, can be formed through single-step wet etching, which facilitates production of the device.

A sixteenth aspect of the present invention is drawn to a specific embodiment of the method for producing a light-emitting device as described in the fifteenth aspect, wherein the first and second trenches are formed through wet etching which is allowed to proceed until etching eventually stops, so that the second trench assumes a V-shape as viewed in a cross section perpendicular to the bottom surface of the growth substrate.

Thus, the first trench and the second trench, which has a depth greater than that of the first trench and is employed for separating the device into chips, can be formed through single-step wet etching. In this case, there is no difference in first or second trench depth between devices produced. Therefore, the devices exhibit uniform light output characteristics.

A seventeenth aspect of the present invention is drawn to a specific embodiment of the method for producing a light-emitting device as described in any one of the first to sixteenth aspects, wherein the light-emitting device is of a face-up type, and the mask has a pattern which allows the center of a pad to fall within an outwardly convex region defined by a closed curve, the region including the entire pattern of the mask and having the smallest possible area.

An eighteenth aspect of the present invention is drawn to a specific embodiment of the method for producing a light-emitting device as described in any one of the first to seventeenth aspects, wherein the growth substrate has an absorption coefficient of 3/cm or less with respect to light emitted from the light-emitting device.

As used herein, “absorption coefficient” of a medium indicates the degree of absorption of light by the medium when light passes therethrough. When I₀ represents the intensity of light before entering a medium, I represents the intensity of light which has passed through the medium, α represents absorption coefficient, and x represents the distance over which light has traveled through the medium, the following relation is obtained: I=I₀exp (−αx).

In a nineteenth aspect of the present invention, there is provided a light-emitting device comprising a Group III nitride semiconductor growth substrate, and a Group III nitride semiconductor layer stacked on the top surface of the growth substrate, wherein the growth substrate has an embossment including a portion of the bottom surface of the growth substrate, the portion being a planar surface, and a tapered surface which extends from the periphery of the planar surface and is inclined with respect to the growth substrate; and the tapered surface is formed through wet etching.

A twentieth aspect of the present invention is drawn to a specific embodiment of the light-emitting device as described in the nineteenth aspect, wherein the tapered surface is formed so as to attain a depth of 5 μm or more as measured from the bottom surface of the growth substrate.

A twenty-first aspect of the present invention is drawn to a specific embodiment of the light-emitting device as described in the nineteenth aspect, wherein the tapered surface is formed so as to attain a depth which is 40 to 70% of the thickness of the growth substrate.

A twenty-second aspect of the present invention is drawn to a specific embodiment of the light-emitting device as described in any one of the nineteenth to twenty-first aspects, wherein the tapered surface is inclined by 20° to 70° with respect to the growth substrate.

A twenty-third aspect of the present invention is drawn to a specific embodiment of the light-emitting device as described in any one of the nineteenth to twenty-first aspects, wherein the tapered surface is inclined by 60° with respect to the growth substrate.

As described above, “60°” refers not to 60° strictly, but to an angle of 60°±50°.

A twenty-fourth aspect of the present invention is drawn to a specific embodiment of the light-emitting device as described in any one of the nineteenth to twenty-third aspects, wherein the growth substrate is a GaN substrate.

A twenty-fifth aspect of the present invention is drawn to a specific embodiment of the light-emitting device as described in any one of the nineteenth to twenty-fourth aspects, wherein the growth substrate is a C-plane substrate, and the bottom surface of the growth substrate is an N-polar surface.

A twenty-sixth aspect of the present invention is drawn to a specific embodiment of the light-emitting device as described in any one of the nineteenth to twenty-fifth aspects, wherein the embossment comprises one or more protrusions.

A twenty-seventh aspect of the present invention is drawn to a specific embodiment of the light-emitting device as described in any one of the nineteenth to twenty-fifth aspects, wherein the embossment comprises one dent provided at the center of the bottom surface of the growth substrate.

A twenty-eighth aspect of the present invention is drawn to a specific embodiment of the light-emitting device as described in any one of the nineteenth to twenty-seventh aspects, wherein the embossment has a bottom surface which is parallel to the bottom surface of the growth substrate.

A twenty-ninth aspect of the present invention is drawn to a specific embodiment of the light-emitting device as described in any one of the nineteenth to twenty-eighth aspects, wherein the embossment comprises a plurality of protrusions, and a first trench formed between adjacent protrusions assumes a V-shape as viewed in a cross section perpendicular to the bottom surface of the growth substrate.

A thirtieth aspect of the present invention is drawn to a specific embodiment of the light-emitting device as described in the twenty-ninth aspect, wherein a plurality of first trenches have different depths.

A thirty-first aspect of the present invention is drawn to a specific embodiment of the light-emitting device as described in any one of the nineteenth to thirtieth aspects, wherein the embossment comprises a plurality of protrusions, and includes a first trench which is formed between adjacent protrusions and assumes a V-shape as viewed in a cross section perpendicular to the bottom surface of the growth substrate, and a side surface of a second trench which has a depth greater than that of the first trench and is formed at a position at which the light-emitting device is separated into chips.

A thirty-second aspect of the present invention is drawn to a specific embodiment of the light-emitting device as described in the thirty-first aspect, wherein the second trench assumes a V-shape as viewed in a cross section perpendicular to the bottom surface of the growth substrate.

A thirty-third aspect of the present invention is drawn to a specific embodiment of the light-emitting device as described in any one of the nineteenth to thirty-second aspects, wherein the light-emitting device is of a face-up type, and the mask has a pattern which allows the center of a pad to fall within an outwardly convex region defined by a closed curve, the region including the entire pattern of the mask and having the smallest possible area.

A thirty-fourth aspect of the present invention is drawn to a specific embodiment of the light-emitting device as described in any one of the nineteenth to thirty-third aspects, wherein the growth substrate has an absorption coefficient of 3/cm or less with respect to light emitted from the light-emitting device.

According to the first aspect of the present invention, since the bottom surface of the growth substrate is planarized, an etchant does not enter a space below the mask, and a region directly below the mask is not etched. Therefore, the bottom surface of the growth substrate can be accurately etched in a predetermined pattern at high reproducibility. Such high reproducibility in etching can reduce variation in brightness or light distribution. Since wet etching of a Group III nitride semiconductor occurs anisotropically, a tapered portion can be readily formed through wet etching, and no damage occurs on a tapered surface which is exposed through wet etching. As described above, a light-emitting device exhibiting improved light extraction performance by virtue of its bottom-tapered growth substrate can be readily produced at high reproducibility, as compared with conventional cases. When a region of the thus-tapered growth substrate corresponding to chip separation is thinned through etching, subsequent chip separation is readily carried out.

According to the second aspect of the present invention, the bottom surface of the growth substrate may be planarized through chemical mechanical polishing.

When etching is carried out to a depth of 5 μm or more as measured from the bottom surface of the growth substrate (third aspect) or to a depth which is 40 to 70% of the thickness of the growth substrate (fourth aspect), light extraction performance can be improved. When a chip separation region is thinned through etching, subsequent chip separation is more readily carried out.

When a tapered surface is inclined with respect to the growth substrate by 20° to 70° (fifth aspect) or 60° (sixth aspect), light extraction performance can be further improved.

According to the seventh aspect of the present invention, since phosphoric acid is employed for etching, by virtue of anisotropic etching of a Group III nitride semiconductor with phosphoric acid, the bottom surface of the growth substrate is readily processed so that a tapered surface is exposed. In this case, roughness of the etched surface is reduced.

According to the eighth aspect of the present invention, since the growth substrate is a C-plane substrate, and the bottom surface of the growth substrate is an N-polar surface, etching of the Group III nitride semiconductor is more readily carried out.

According to the ninth aspect of the present invention, the growth substrate may be a GaN substrate.

The embossment of the growth substrate may comprise one or more protrusions (tenth aspect), or one dent provided at the center of the bottom surface of the growth substrate (eleventh aspect). Alternatively, the embossment of the growth substrate may have an exposed bottom surface which is parallel to the bottom surface of the growth substrate (through etching of the twelfth aspect).

According to the thirteenth aspect of the present invention, when a first trench is formed through wet etching so that the trench assumes a V-shape as viewed in a cross section perpendicular to the bottom surface of the growth substrate, etching automatically stops upon completion of formation of the V-shaped trench. Therefore, the depth of the first trench can be controlled by only determining the size of the corresponding opening of the mask. Thus, there can be produced devices having first trenches of uniform depth; i.e., devices exhibiting uniform performance.

According to the fourteenth aspect of the present invention, when the size of first openings of the mask is varied to a predetermined value, and wet etching is allowed to proceed until etching eventually stops, the depth profile of a plurality of first trenches can be controlled to a desired one. Thus, devices exhibiting uniform emission output can be produced.

According to the fifteenth aspect of the present invention, a first trench and a second trench—which has a depth greater than that of the first trench and is employed for separating the device into chips—can be formed through single-step wet etching, which facilitates production of the device.

According to the sixteenth aspect of the present invention, a first trench and a second trench—which has a depth greater than that of the first trench and is employed for separating the device into chips—can be formed through single-step wet etching. In this case, there is no difference in first or second trench depth between devices produced. Therefore, the devices exhibit uniform light output characteristics.

In the case where the pattern (in plan view) of the mask is determined as described above (seventeenth aspect), even when the light-emitting device is of a face-up type, a chip can be prevented from being inclined during wire bonding.

According to the eighteenth aspect of the present invention, since the growth substrate is a substrate having a light absorption coefficient of 3/cm or less with respect to light emitted from the light-emitting device, light extraction performance can be more improved. Employment of a substrate having an absorption coefficient of 1/cm or less is preferred, from the viewpoint of further improvement of light extraction performance.

According to the nineteenth to thirty-fourth aspects of the present invention, a light-emitting device exhibiting improved light extraction performance can be realized.

### BRIEF DESCRIPTION OF THE DRAWINGS

Various other objects, features, and many of the attendant advantages of the present invention will be readily appreciated as the same becomes better understood with reference to the following detailed description of the preferred embodiments when considered in connection with the accompanying drawings, in which:

FIG. 1 shows the structure of a light-emitting device 1 according to Embodiment 1;

FIGS. 2A to 2F show a production process of the light-emitting device 1 according to Embodiment 1;

FIG. 3 shows the structure of a light-emitting device 2 according to Embodiment 2;

FIGS. 4A, 4B show a production process of the light-emitting device 2 according to Embodiment 2;

FIG. 5 shows the structure of a light-emitting device 3 according to Embodiment 3;

FIG. 6 shows the pattern of masks 34;

FIG. 7 is graphs showing data on light distribution characteristics;

FIG. 8 shows data on light distribution characteristics;

FIG. 9 shows the structure of a light-emitting device 4 according to Embodiment 4;

FIG. 10 shows the pattern of a mask 44;

FIGS. 11A to 11C show a production process of the light-emitting device 4 according to Embodiment 4;

FIG. 12 schematically shows stages of etching with phosphoric acid;

FIG. 13 shows an example that the depth of a dent formed through etching with phosphoric acid can be controlled only by the size of the corresponding opening provided in a mask;

FIG. 14 shows another example that the depth of a dent formed through etching with phosphoric acid can be controlled only by the size of the corresponding opening provided in a mask; and

FIG. 15 shows an example of a mask pattern formed on the bottom surface of a GaN substrate.

### DETAILED DESCRIPTION OF PREFERRED EMBODIMENTS

Specific embodiments of the present invention will next be described with reference to the drawings. However, the present invention is not limited to the embodiments.

### Embodiment 1

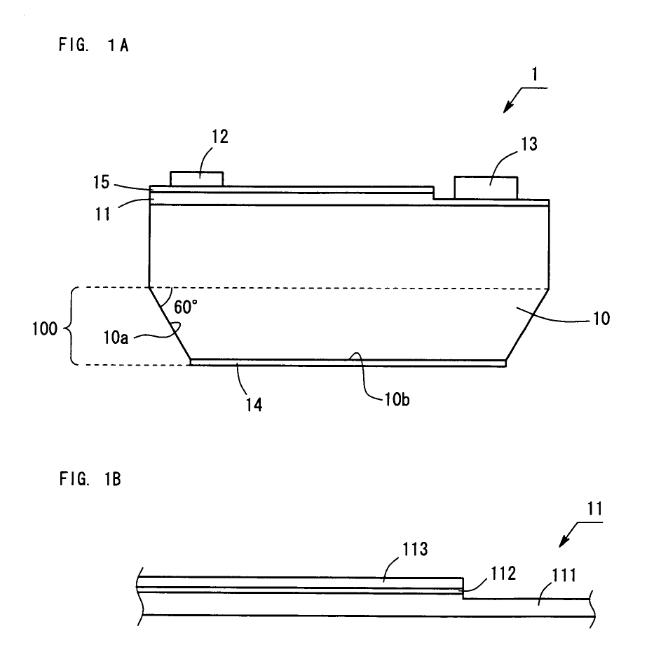

FIG. 1 shows the structure of a face-up-type light-emitting device 1 according to Embodiment 1. The light-emitting device 1 has a size of about 350 μm×about 350 μm.

The structure of the light-emitting device 1 will now be described. As shown in FIG. 1A, the light-emitting device 1 includes a GaN substrate 10 serving as a growth substrate; a Group III nitride semiconductor layer 11 formed on the top surface of the GaN substrate 10; an ITO electrode 15 formed on the top surface of the semiconductor layer 11; a p-electrode 12; an n-electrode 13; and an SiO₂ mask 14 formed on the bottom surface 10b of the GaN substrate 10.

As shown in FIG. 1B, the semiconductor layer 11 has a structure in which an n-layer 111, an active layer 112, and a p-layer 113 are sequentially stacked. The n-layer 111 has a structure in which an n-type GaN contact layer doped with Si at high concentration and a GaN n-cladding layer are sequentially stacked. The p-layer 113 has a structure in which an Mg-doped AlGaN p-cladding layer and an Mg-doped GaN p-contact layer are sequentially stacked. The active layer 112 has an MQW structure in which GaN barrier layers and InGaN well layers are repeatedly stacked. The active layer 112 and the p-layer 113 are partially etched, and a portion of the n-layer 111 is exposed.

The ITO electrode 15 is formed on the p-layer 113 so as to cover almost the entire surface of the p-layer 113. The p-electrode 12 is formed in a predetermined pattern on a region of the ITO electrode 15. The n-electrode 13 is formed on the exposed portion of the n-layer 111.

The GaN substrate 10 has a thickness of about 185 μm. The bottom surface 10b of the GaN substrate 10 generally coincides with the shape of a mask 14 having a size of 250 μm×250 μm. The bottom surface 10b of the GaN substrate 10 covered with the mask 14 corresponds to the planar surface of the present invention. The GaN substrate 10 has a truncated pyramidal protrusion 100 whose horizontal cross-sectional area increases toward the side of the top surface of the GaN substrate 10 (depth: about 85 μm as measured from the bottom surface 10b of the GaN substrate 10). The protrusion 100 has a tapered surface 10a which is inclined by about. 60° with respect to the GaN substrate 10. The tapered surface 10a is exposed by virtue of anisotropy in wet etching. The GaN substrate 10 is a C-plane substrate, and the bottom surface of the GaN substrate 10 is an N-polar surface.

The GaN substrate 10 preferably has an absorption coefficient of 3/cm or less with respect to the wavelength of light emitted from the light-emitting device 1. When the absorption coefficient is 3/cm or less, light extraction performance can be considerably improved. The absorption coefficient is more preferably 1/cm or less.

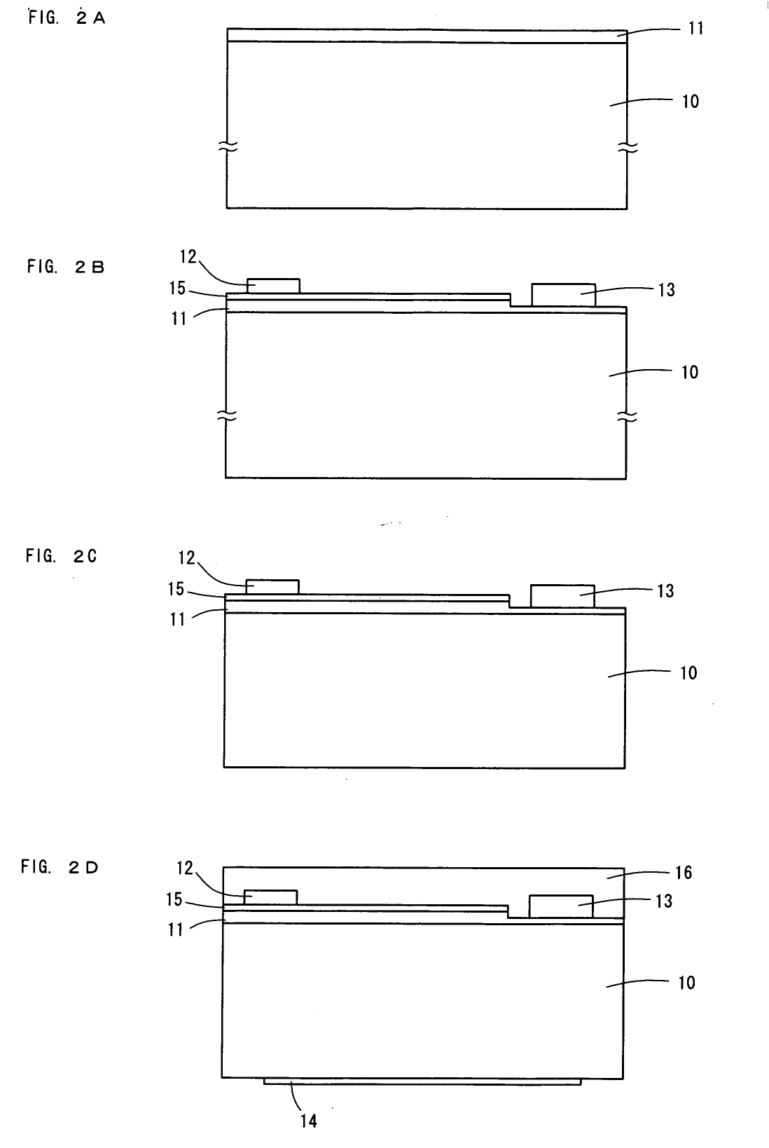

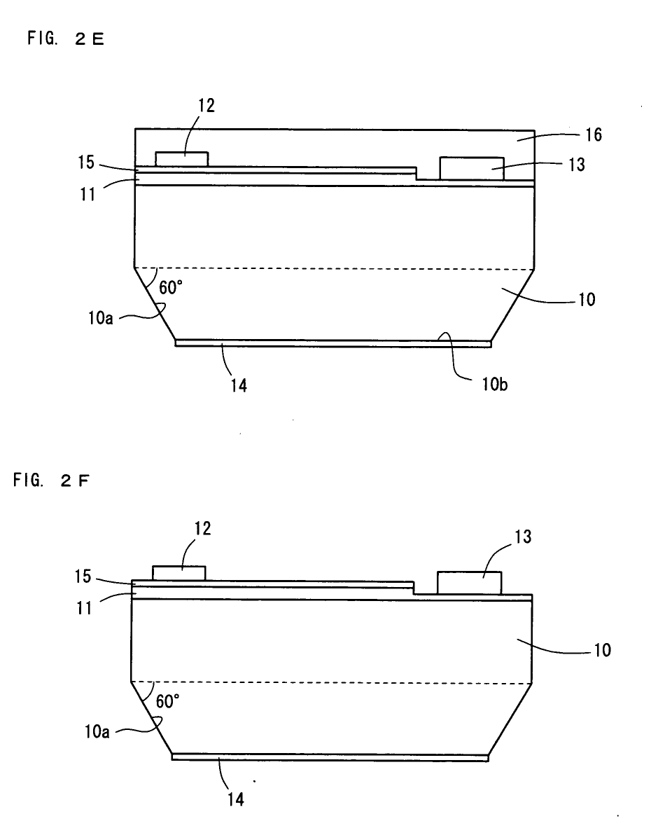

Next will be described a method for producing the light-emitting device 1 with reference to FIGS. 2A to 2F (production process diagrams). Firstly, an n-layer 111, an MQW layer 112, and a p-layer 113 are stacked on the top surface of a GaN substrate 10 (thickness: about 350 μm) through MOCVD, to thereby form a semiconductor layer 11 (FIG. 2A). The GaN substrate 10 is a C-plane substrate, and the top surface and the bottom surface of the substrate are a Ga-polar surface and an N-polar surface, respectively. Raw material gases employed for formation of the semiconductor layer 11 are as follows: ammonia (NH₃) serving as a nitrogen source, trimethylgallium (Ga(CH₃)₃) serving as a Ga source, trimethylindium (In(CH₃)₃) serving as an In source, trimethylaluminum (Al(CH₃)₃) serving as an Al source, silane (SiH₄) serving as an n-type doping gas, and cyclopentadienylmagnesium (Mg(C₅H₅)₂) serving as a p-type doping gas. H₂ or N₂ is employed as a carrier gas.

Subsequently, an ITO electrode 15 is formed on the p-GaN layer 113 through vapor deposition, followed by annealing. Then, the ITO electrode 15 is processed through photolithography and wet etching so as to have a predetermined pattern. Subsequently, a portion of the n-layer 111 is exposed through photolithography and dry etching. Thereafter, a resist mask is formed through photolithography, and electrode materials are deposited, followed by the lift-off process, to thereby form a p-electrode 12 on the ITO electrode 15 and to form an n-electrode 13 on the exposed portion of the n-layer 111 so that each of the electrodes has a predetermined pattern (FIG. 2B).

Subsequently, the bottom surface of the GaN substrate 10 is mechanically polished so as to attain a thickness of about 185 μm. Then, the bottom surface is planarized through chemical mechanical polishing (CMP) (FIG. 2C). As used herein, “planarizing” refers to a step of reducing irregularities on the bottom surface of the growth substrate, and removing a damaged layer formed by mechanical polishing. For example, colloidal silica particles are employed as an abrasive for CMP, and phosphoric acid or the like is employed as an etchant.

Subsequently, an SiO₂ mask 14 (thickness: 300 nm) is formed on the bottom surface 10b of the GaN substrate 10 through PECVD, and then the mask 14 is processed through photolithography and dry etching so as to have a size of 250 μm×250 μm. A resist film 16 is formed on the side of the top surface of the GaN substrate 10 so that the above-formed layered structure is protected from subsequent wet etching (FIG. 2D). The mask 14 is not necessarily formed through PECVD and may be formed from SiO₂ through sputtering or a similar technique. Alternatively, the mask 14 may be formed of a material exhibiting corrosion resistance to the etchant, such as oxide film, nitride film, metal film, or resist material. The film for protecting the layered structure from wet etching may be, in addition to the aforementioned resist film 16, a film formed of, for example, wax; i.e., a material which exhibits resistance to an etchant employed and is readily removed after completion of etching.

Subsequently, the GaN substrate 10 is wet-etched with phosphoric acid (concentration: 85%) at 150° C. for 90 minutes. Etching of GaN with phosphoric acid exhibits anisotropy, and thus the GaN substrate 10 is etched to a depth of about 85 μm so as to assume a tapered form (FIG. 2E), whereby four tapered surfaces 10a are exposed. Each of the tapered surfaces 10a has one side shared with the quadrangular mask 14, and is inclined by about 60° with respect to the GaN substrate 10. Since the bottom surface 10b of the GaN substrate 10 is planarized through CMP, etching is accurately carried out according to the pattern of the mask. Through such wet etching, roughness of the tapered surfaces 10a is reduced, and the GaN substrate is processed at high reproducibility.

When CMP treatment is carried out insufficiently, a damaged layer formed by mechanical polishing is preferentially etched at an initial stage of wet etching, whereby scratches are formed. In the presence of the thus-formed scratches, phosphoric acid (i.e., etchant) enters a space below the mask 14, and the accuracy of patterning is reduced. Therefore, it should be noted that the bottom surface 10b of the GaN substrate 10 is planarized to a maximum possible extent, and that CMP treatment must be carried out so as to appropriately remove a mechanically damaged layer.

Etching rate can be controlled by varying the temperature or concentration of phosphoric acid. The phosphoric acid temperature is preferably 100 to 200° C. This is because, when the phosphoric acid temperature is 100° C. or lower, etching rate is reduced (i.e., etching requires a long period of time), whereas when the phosphoric acid temperature is 200° C. or higher, the mask 14 may be damaged. The phosphoric acid concentration is preferably 1% or more. This is because, when the phosphoric acid concentration is less than 1%, etching rate is reduced.

The etchant employed for the aforementioned wet etching may be, in addition to phosphoric acid, for example, pyrophosphoric acid, mixed acid of phosphoric acid and sulfuric acid, potassium hydroxide, or sodium hydroxide. Preferably, the etching depth is 5 μm or more as measured from the bottom surface of the GaN substrate 10, or is 40 to 70% of the thickness of the GaN substrate 10. When the etching depth is 5 μm or more, or is 40 to 70% of the thickness of the GaN substrate 10, light extraction performance can be further improved. When a chip separation portion of the GaN substrate 10 is thinned through etching, subsequent chip separation is more readily carried out. The tapered surfaces 10a are preferably inclined by 20° to 70° with respect to the GaN substrate 10. When the tapered surfaces 10a are inclined by an angle falling within the above range, light extraction performance can be further improved.

Subsequently, the resist film 16 is removed from the GaN substrate 10, and scribing and breaking are carried out on the side of the top surface of the GaN substrate 10 at a position where the above-etched GaN substrate 10 has the smallest thickness, to thereby separate the light-emitting device 1 into chips, each having a size of 350 μm×350 μm (FIG. 2F). Since a portion of the GaN substrate 10 is thinned through wet etching, chip separation is more readily carried out, as compared with conventional cases.

The thus-produced light-emitting device 1 was face-up mounted on a board, and light output was measured. As a result, light extraction performance was found to be increased by about 10%, as compared with the case of a light-emitting device including a GaN substrate 10 whose bottom surface is not processed as described above. Since tapering was carried out through wet etching, high reproducibility was attained, and variation in brightness or light distribution was reduced.

In Embodiment 1, the GaN substrate 10 is mechanically polished so as to attain a thickness of about 185 μm. However, the thickness of the GaN substrate after mechanical polishing is not limited to this value. The same shall apply to the below-described embodiments.

### Embodiment 2

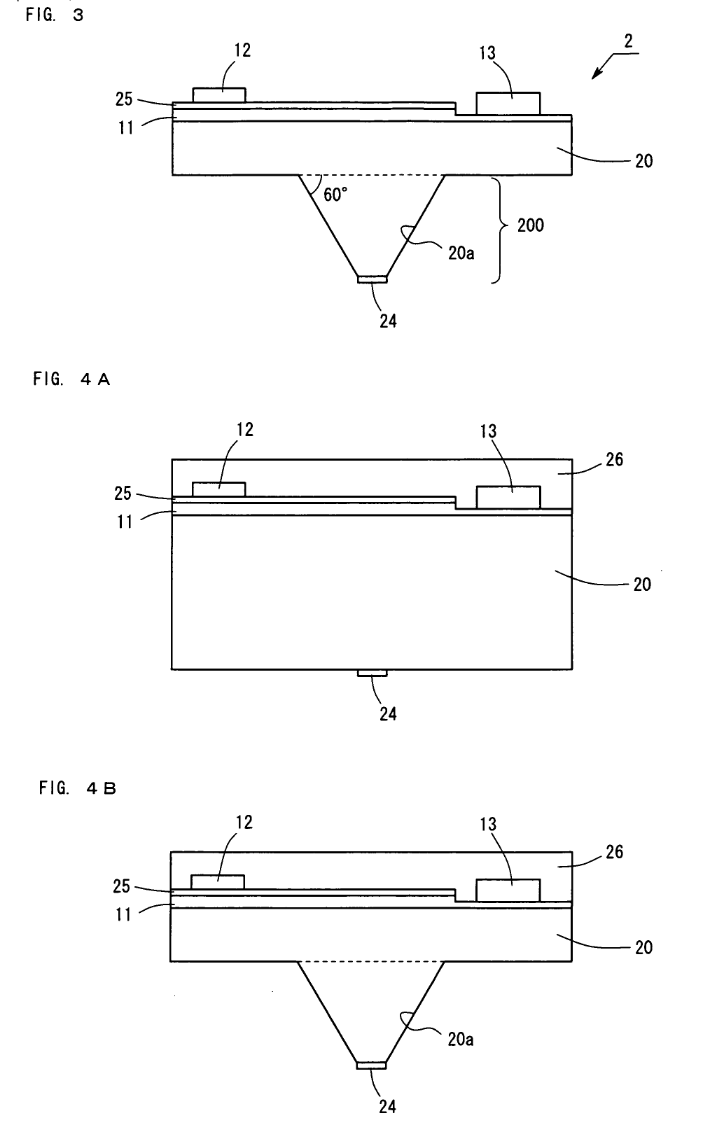

FIG. 3 shows the structure of a face-down-type light-emitting device 2 according to Embodiment 2. The light-emitting device 2 has a structure including a GaN substrate 20, a semiconductor layer 11 formed on the top surface of the substrate 20, a highly reflective Ag electrode 25, a p-electrode 12, and an n-electrode 13. As in the case of the light-emitting device 1 according to Embodiment 1, the light-emitting device 2 has a size of about 350 μm×about 350 μm. The main difference between the light-emitting device 2 and the light-emitting device 1 is attributed to the difference in form between the processed GaN substrate 20 and the processed GaN substrate 10.

The GaN substrate 20 is a C-plane substrate having a thickness of 185 μm, and the bottom surface of the substrate is an N-polar surface. The GaN substrate 20 has an absorption coefficient of 3/cm or less with respect to the wavelength of light emitted from the light-emitting device 2. The bottom surface 20b of the GaN substrate 20 generally coincides with a mask 24 having a size of 20 μm×20 μm. The bottom surface 20b of the GaN substrate 20 covered with the mask 24 corresponds to the planar surface of the present invention. The GaN substrate 20 has a truncated pyramidal protrusion 200 between the bottom surface 20b and a depth of about 120 μm. The protrusion 200 has a quadrangular top surface (corresponding to the bottom surface 20b of the GaN substrate 20) and a dodecagonal bottom surface, in which horizontal cross-sectional area increases toward the side of the top surface of the GaN substrate 20. The GaN substrate 20 assumes a rectangular parallelepiped form (size: about 350 μm×about 350 μm, thickness: about 65 μm) between a depth of about 120 μm and a depth of 185 μm as measured from the bottom surface. Therefore, a bottom surface 20c parallel to the bottom surface 20b of the GaN substrate 20 is formed at a depth of about 120 μm as measured from the bottom surface 20b. The bottom surface 20c corresponds to “bottom surface parallel to the bottom surface of the growth substrate” of the present invention. The protrusion 200 has a tapered surface 20a which is inclined by about 60° with respect to the GaN substrate 20. The tapered surface 20a is exposed by virtue of anisotropy in wet etching.

Next will be described a method for producing the light-emitting device 2 with reference to FIGS. 4A and 4B. The light-emitting device 2 is produced through the same procedure as in the case of the light-emitting device 1 according to Embodiment 1, except that the ITO electrode 15 is replaced with a highly reflective electrode 25, and the step of processing the bottom surface of the GaN substrate 20 is carried out in a manner different from that described above. Therefore, now will be described only the step of processing the bottom surface of the GaN substrate 20, and steps subsequent thereto.

After planarizing of the bottom surface of the GaN substrate 20 through CMP, an SiO₂ mask 24 (thickness: 300 nm) is formed on the bottom surface of the GaN substrate 20 through PECVD, and then the mask 24 is processed through photolithography and dry etching so as to have a size of 20 μm×20 μm. A resist film 26 is formed on the side of the top surface of the GaN substrate 20 so that the layered structure is protected from subsequent wet etching (FIG. 4A).

Subsequently, the GaN substrate 20 is wet-etched with phosphoric acid (concentration: 85%) at 150° C. to a depth of 120 μm, to thereby form a truncated pyramidal protrusion (FIG. 4B). Thus, a tapered surface 20a is exposed by virtue of anisotropy in etching of GaN with phosphoric acid. The tapered surface 20a is inclined by about 600 with respect to the GaN substrate 20.

Thereafter, in a manner similar to that of Embodiment 1, the resist film 26 is removed from the GaN substrate 20, and scribing and breaking are carried out on the side of the top surface of the GaN substrate 20 at a predetermined position, to thereby separate the-light-emitting device 2 into chips, each having a size of 350 μm×350 μm.

The thus-produced light-emitting device 2 was flip-chip mounted on a board, and light output was measured. As a result, light extraction performance was found to be increased by about 15%, as compared with the case of a light-emitting device including a GaN substrate 20 whose bottom surface is not processed as described above. Similar to the case of Embodiment 1, tapering was carried out at high reproducibility, and variation in brightness or light distribution was reduced.

### Embodiment 3

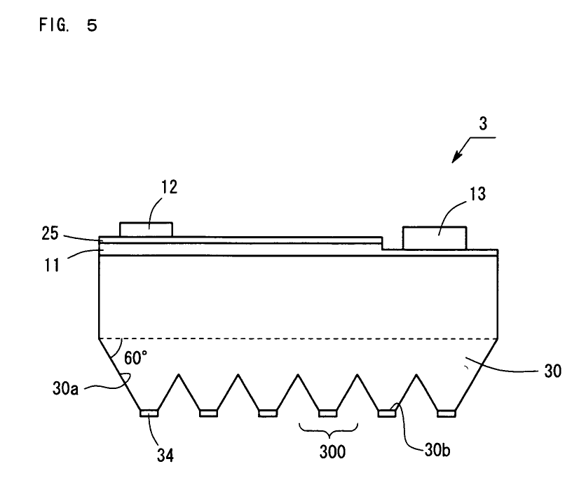

FIG. 5 shows the structure of a light-emitting device 3 according to Embodiment 3. Similar to the case of the light-emitting device 2 according to Embodiment 2, the light-emitting device 3 has a structure including a GaN substrate 30, a semiconductor layer 11 formed on the top surface of the substrate 30, a highly reflective electrode 25, a p-electrode 12, and an n-electrode 13. As in the case of the light-emitting device 2 according to Embodiment 2, the light-emitting device 3 has a size of about 350 μm×about 350 μm. The main difference between the light-emitting device 3 and the light-emitting device 2 is attributed to the difference in form between the processed GaN substrate 30 and the processed GaN substrate 20.

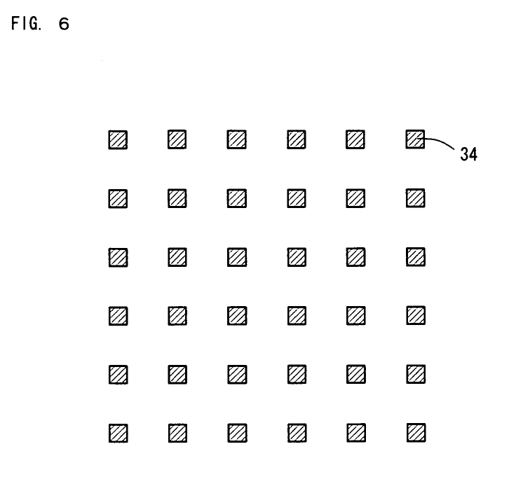

The GaN substrate 30 is a C-plane substrate having a thickness of 185 μm, and the bottom surface of the substrate is an N-polar surface. The GaN substrate 30 has an absorption coefficient of 3/cm or less with respect to the wavelength of light emitted from the light-emitting device 3. The bottom surface 30b of the GaN substrate 30 generally coincides with a pattern of masks 34 (size: 20 μm×20 μm each) which are arranged in a 6×6 matrix form (see FIG. 6). The bottom surface 30b of the GaN substrate 30 covered with the masks 34 corresponds to the planar surface of the present invention. The GaN substrate 30 has 36 truncated pyramidal protrusions 300 whose horizontal cross-sectional area increases from the bottom surface 30b toward the side of the top surface of the GaN substrate 30, and the protrusions 300 are arranged in a 6×6 matrix form. Each of the protrusions 300 has a tapered surface 30a which is inclined by about 60° with respect to the GaN substrate 30. The tapered surface 30a is exposed by virtue of anisotropy in wet etching. The 36 truncated pyramidal protrusions, each having the bottom surface 30b of the GaN substrate 30 and a tapered surface 30a, correspond to the protrusions of the present invention.

The light-emitting device 3 can be produced in the same procedure as in the light-emitting device 2 according to Embodiment 2, except that masks formed on the bottom surface 30b of the GaN substrate 30 are arranged in a pattern shown in FIG. 6.

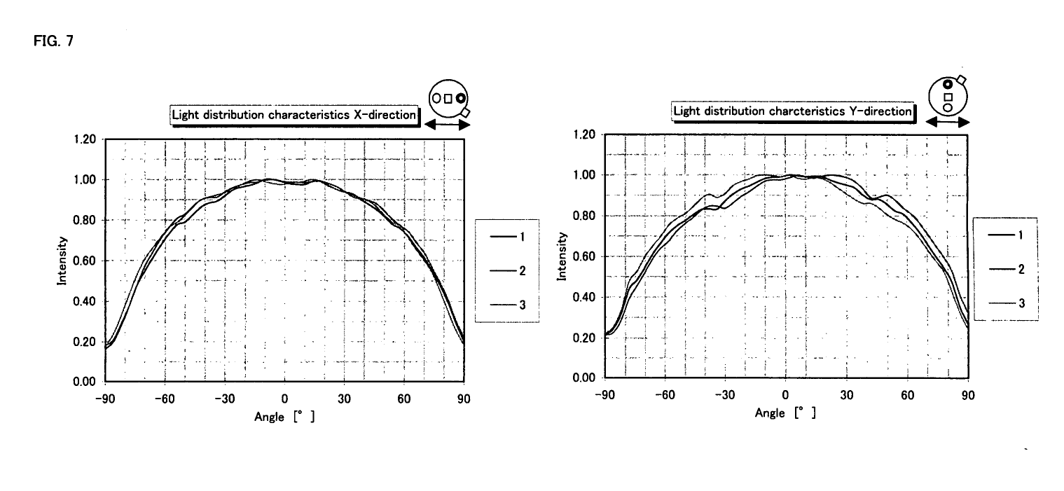

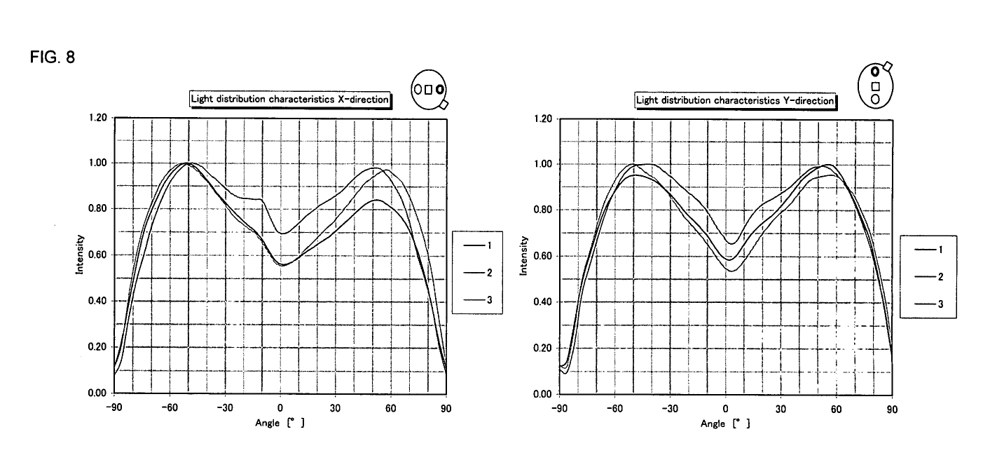

FIG. 7 shows the results of measurement of light distribution characteristics of three flip-chip-mounted light-emitting devices 3. For comparison, light distribution characteristics of three flip-chip-mounted light-emitting devices, each including a substrate 30 having an unprocessed bottom surface 30b, were measured (FIG. 8). Comparison between FIGS. 7 and 8 shows that the light-emitting devices 3 exhibit a small variation in light intensity with angle, whereas the comparative light-emitting devices (each including a substrate 30 having an unprocessed bottom surface 30b) exhibit low light intensity in the vicinity of the center, and a large variation in light intensity with angle. These data indicate that variation in light distribution can be reduced through tapering of the bottom surface 30b of the substrate 30. As is clear from FIGS. 7 and 8, a variation in brightness between the three light-emitting devices 3 is smaller than that between the three comparative light-emitting devices (each including a substrate 30 having an unprocessed bottom surface 30b).

### Embodiment 4

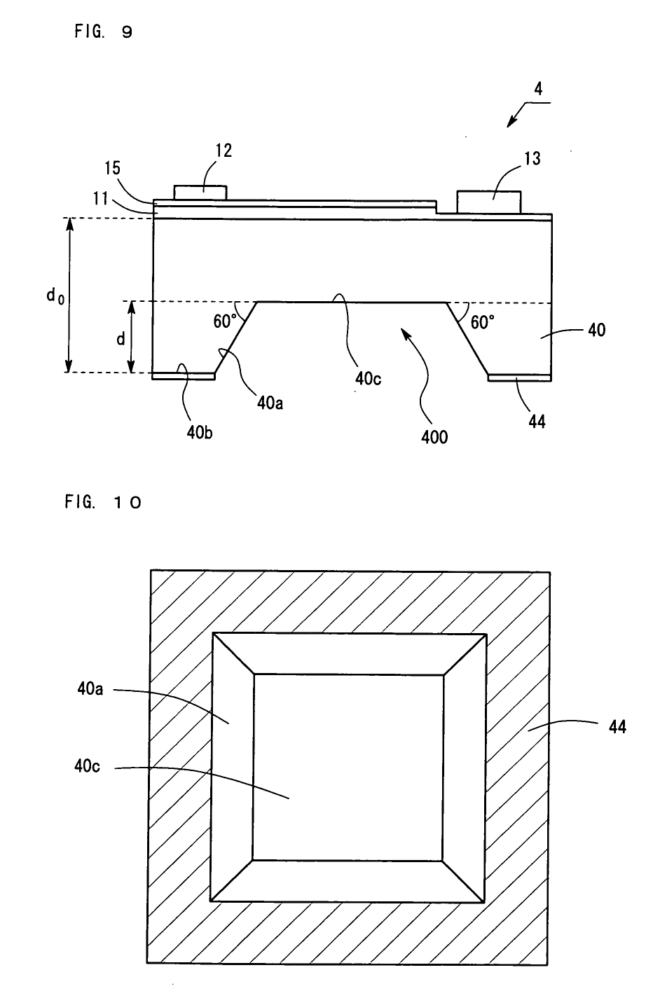

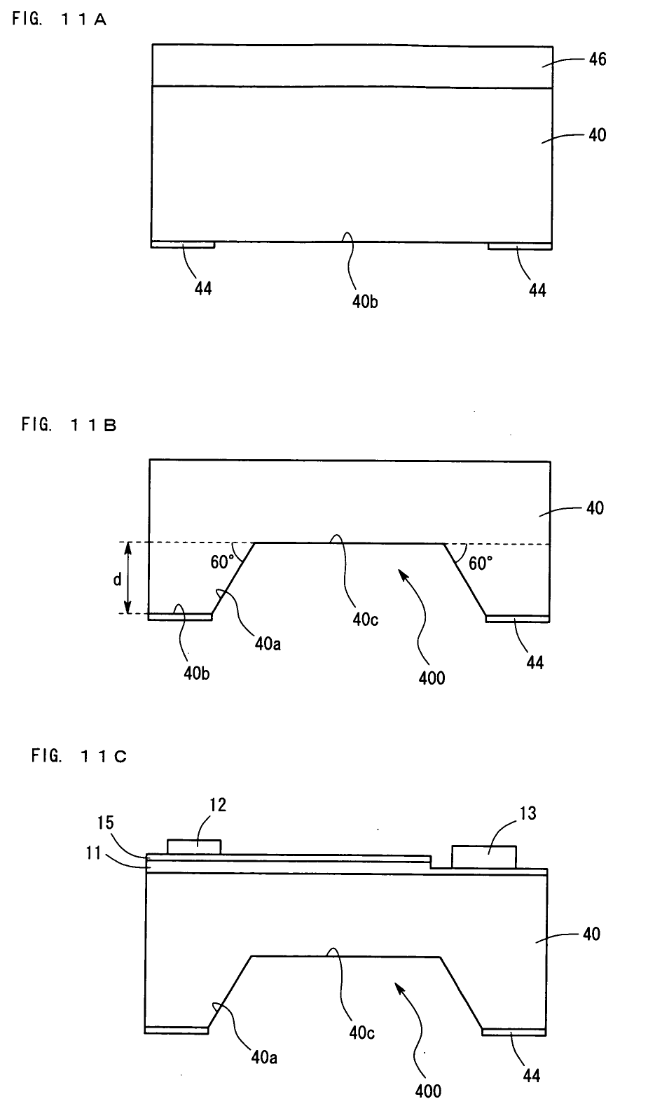

FIG. 9 shows the structure of a light-emitting device 4 according to Embodiment 4. Similar to the case of the light-emitting device 1 according to Embodiment 1, the light-emitting device 4 has a structure including a GaN substrate 40, a semiconductor layer 11 formed on the top surface of the substrate 40, an ITO electrode 15, a p-electrode 12, and an n-electrode 13. As in the case of the light-emitting device 1 according to Embodiment 1, the light-emitting device 4 has a size of about 350 μm×about 350 μm. The main difference between the light-emitting device 4 and the light-emitting device 1 is attributed to the difference in form between the processed GaN substrate 40 and the processed GaN substrate 10.

The GaN substrate 40 is a C-plane substrate, and the bottom surface of the substrate is an N-polar surface. The GaN substrate 40 has an absorption coefficient of 3/cm or less with respect to the wavelength of light emitted from the light-emitting device 4. The bottom surface 40b of the GaN substrate 40 generally coincides with a mask 44 having in its center a square opening (see FIG. 10). The bottom surface 40b of the GaN substrate 40 covered with the mask 44 corresponds to the planar surface of the present invention. The GaN substrate 40 has, in its bottom center portion, a dent 400 corresponding to the opening of the mask 44. The dent 400 assumes a truncated quadrangular pyramidal form and includes a square bottom surface 40c parallel to the bottom surface 40b of the GaN substrate 40 and four tapered surfaces 40a inclined by about 60° with respect to the GaN substrate 40. Each of the tapered surfaces 40a is exposed by virtue of anisotropy in wet etching. The depth d of the dent 400 is preferably 5 μm or more, or 40 to 70% of the thickness d0 of the GaN substrate 40.

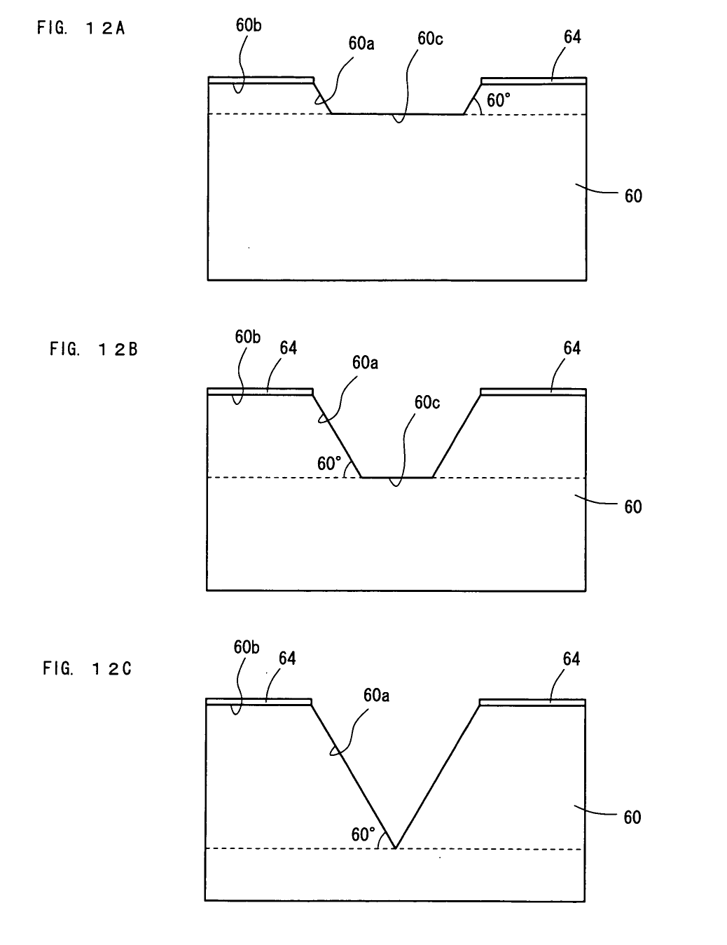

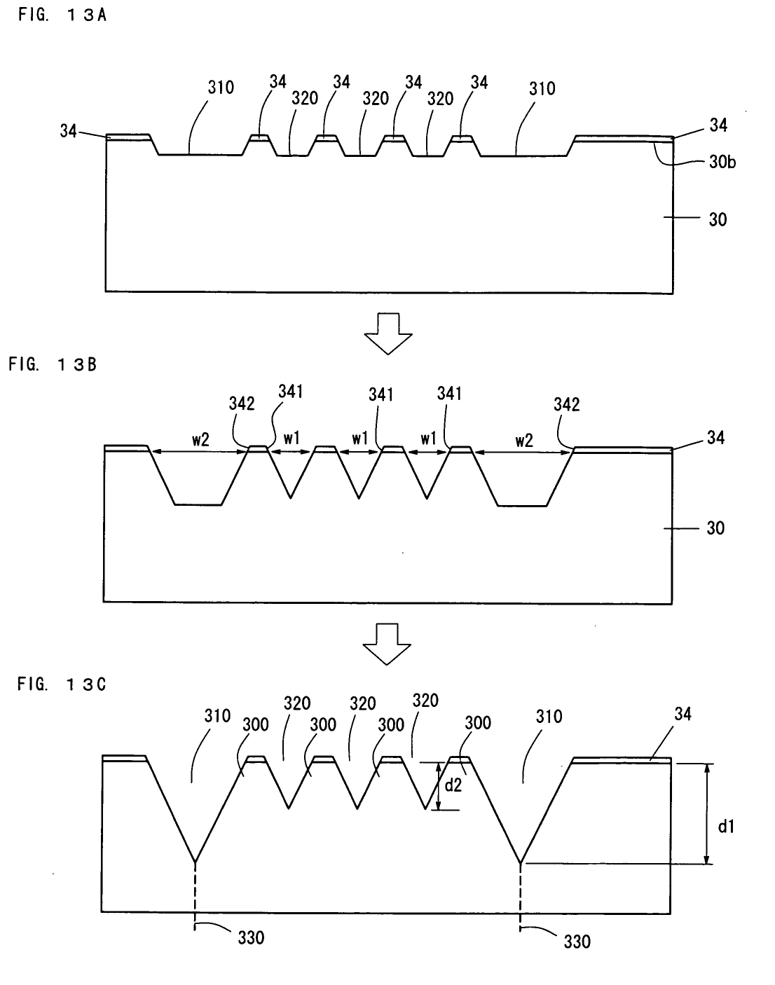

Next will be described a method for producing the light-emitting device 4 with reference to FIGS. 11A to 11C.

Firstly, a GaN substrate (C-plane substrate) 40 whose top surface is a Ga-polar surface and whose bottom surface is an N-polar surface is provided, and the GaN substrate 40 is thinned through mechanical polishing of the bottom surface 40b. Then, the entire bottom surface 40b of the GaN substrate 40 is planarized through dry etching and subsequent high-temperature thermal treatment. As described in the aforementioned embodiments, the term “planarizing” refers to a step of reducing irregularities on the bottom surface 40b of the GaN substrate 40, and removing a damaged layer formed by mechanical polishing. When the bottom surface 40b is planarized before formation of a semiconductor layer 11, such high-temperature thermal treatment can be carried out for planarization.

Subsequently, an SiO₂ mask 44 (thickness: 300 nm) is formed on the bottom surface 40b of the GaN substrate 40 through PECVD, and then the mask 44 is processed through photolithography and dry etching so as to form a square opening. A resist film 46 is formed on the side of the top surface of the GaN substrate 40 so that the top surface of the substrate is protected from subsequent wet etching (FIG. 11A).

Subsequently, the GaN substrate 40 is wet-etched with phosphoric acid (concentration: 85%) at 150° C. Etching of GaN with phosphoric acid exhibits anisotropy, and thus the GaN substrate 40 is etched to have a tapered form, whereby a square bottom surface 40c and four tapered surfaces 40a are exposed. Each of the tapered surfaces 40a is inclined by about 60° with respect to the GaN substrate 40. The bottom surface 40c and the four tapered surfaces (side surfaces) 40a form a truncated quadrangular pyramidal dent 400 having a depth d. Thereafter, the resist film 46 is removed from the GaN substrate 40 (FIG. 11B).

Subsequently, an n-layer 111, an MQW layer 112, and a p-layer 113 are stacked on the top surface of the GaN substrate 40 through MOCVD, to thereby form a semiconductor layer 11. Then, an ITO electrode 15 is formed on the p-GaN layer 113 through vapor deposition, followed by annealing. The ITO electrode 15 is processed through photolithography and wet etching so as to have a predetermined pattern. Thereafter, a portion of the n-layer 111 is exposed through photolithography and dry etching, followed by the lift-off process, to thereby form a p-electrode 12 on the ITO electrode 15 and to form an n-electrode 13 on the exposed portion of the n-layer 111 so that each of the electrodes has a predetermined pattern (FIG. 11C).

Subsequently, scribing and breaking are carried out at a predetermined position of the GaN substrate 40, to thereby separate the light-emitting device 4 into chips, each having a size of 350 μm×350 μm.

The light-emitting device 4 produced through the above-described procedure also exhibits improved light extraction performance, by virtue of the tapered surfaces 40a.

In the production method described in Embodiment 4, the planarizing step, the wet etching step, and the semiconductor layer formation step are carried out in this sequence. However, the planarizing step may be followed by the semiconductor layer formation step, and subsequently followed by the wet etching step. The aforementioned planarizing step employing dry etching and high-temperature thermal treatment may be replaced with a planarizing step employing CMP.

Wet etching of GaN with phosphoric acid employed in all the aforementioned embodiments will next be described in detail with reference to FIG. 12.

FIG. 12 schematically shows the sequence of stages of phosphoric acid wet etching of a GaN substrate 60 (C-plane substrate) having, on its N-polar surface, a mask 64 having an opening. FIG. 12A shows an initial stage of etching; FIG. 12B shows an intermediate stage of etching; and FIG. 12C shows a final stage of etching.

As shown in FIG. 12A, at an initial stage of etching of the GaN substrate 60, a bottom surface 60c parallel to the bottom surface of the GaN substrate 60 is exposed, and a continuous tapered surfaces 60a are exposed between the bottom surface 60c and a surface 60b protected by the mask 64. The tapered surfaces 60a are formed so as to be inclined by about 60° with respect to the GaN substrate 60.

Since etching proceeds while the tapered surfaces 60a—which are inclined by about 60° with respect to the GaN substrate 60—are maintained, as shown in FIG. 12B, the tapered surfaces 60a extend and the area of the bottom surface 60c decreases in accordance with an increase in etching depth.

When etching further proceeds, as shown in FIG. 12C, the bottom surface 60c diminishes and disappears, and the thus-extended tapered surfaces 60a together form a trench having a V-shape as viewed in cross section. At the time of formation of such a V-shaped trench, etching is inhibited from proceeding. Therefore, even if the etching time is further prolonged, virtually no change is observed in etching depth or form of an etched portion.

Thus, when etching is carried out for a sufficiently long period of time, the form of the etched portion no longer varies with etching time. Therefore, the form of the etched portion depends only on the pattern of a mask employed; i.e., the pattern of the mask generally determines the form of the etched portion.

As described above, in the case of wet etching of GaN with phosphoric acid, the form of an etched portion can be varied by tuning the etching time. When etching is carried out for a sufficiently long period of time, the form of an etched portion can be determined only by the pattern of a mask employed. Thus, variation in form of etched portions between devices can be reduced. In the case of etching with phosphoric acid, a tapered surface is exposed, regardless of mask pattern. Therefore, a mask having a predetermined pattern including a free curve may be employed for etching of GaN for exposure of a tapered surface.

As described below, a method in which etching is carried out for a sufficiently long period of time and the form of an etched portion is controlled only by the pattern of a mask may be applied to, for example, the light-emitting device according to embodiment 3 shown in FIG. 5. As shown in FIG. 13, an SiO₂ mask 34 is formed on the bottom surface 30b of a GaN substrate 30. In this case, the mask 34 is formed to have a pattern such that the area and width w2 of second openings 342 of the mask 34—which openings correspond to separation regions (second trenches) 310 that are located at separation lines 330 for separating the device into chips—are greater than the area and width w1 of first openings 341 of the mask 34 corresponding to first trenches 320 which are removed through etching. With this mask pattern, etching can be carried out so that the depth d1 of the separation regions (second trenches) 310 is greater than the depth d2 of the first trenches 320 located between protrusions 300. Thus, the protrusions 300 and the separation regions (second trenches) 310 for chip separation can be formed through only a single etching step employing the mask 34 having openings of different sizes, which facilitates production of the device.

In this case, when wet etching is allowed to proceed until etching eventually stops, the first trenches 320 and the separation regions (second trenches) 310 assume a sharp-pointed V-shape as viewed in a cross section perpendicular to the bottom surface 30b of the GaN substrate 30. The depth of the V-shaped separation regions 310 can be controlled to be greater than that of the V-shaped first trenches 320. Since etching automatically stops upon completion of formation of the V-shaped trenches, devices having trenches of uniform depth are produced; i.e., the devices exhibit uniform characteristics.

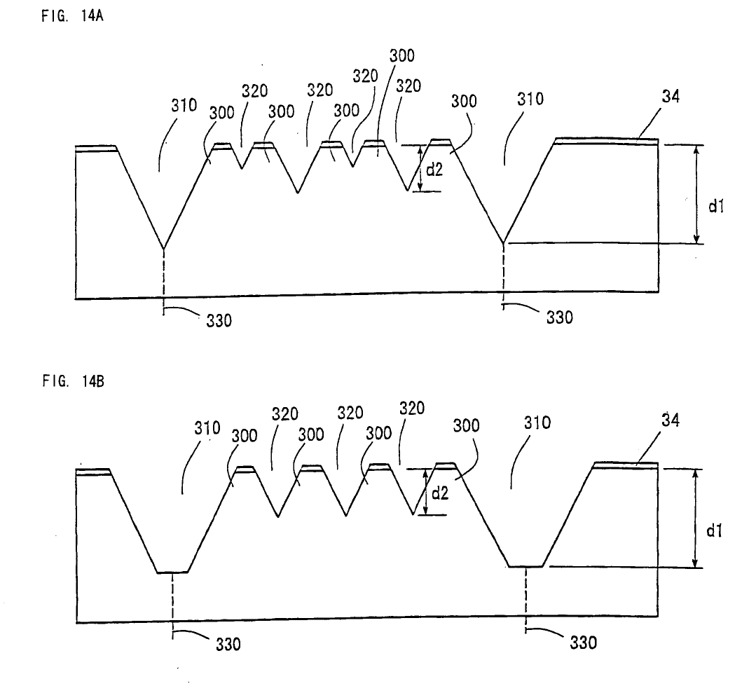

As shown in FIG. 14A, when a plurality of V-shaped first trenches 320 of different depths are formed between protrusions 300, the depth profile of the V-shaped first trenches 320 can be controlled by modifying the sizes of first openings 341 of the mask 34 for forming the first trenches 320. Thus, the protrusions 300, which are provided for further improvement of light extraction performance, are readily designed and produced.

As shown in FIG. 14B, formation of first trenches 320 and separation regions (second trenches) 310 may be controlled by the etching time. In this case, the etching time is determined so that, at the time of termination of etching, the first trenches 320 assume a V-shape as viewed in a cross section perpendicular to the bottom surface of the substrate. The depth of the separation regions (second trenches) 310 is controlled by the etching time. The separation regions 310, each having tapered side surfaces, may have a planar bottom. Light output characteristics of a light-emitting device are affected by the depth of the first trenches 320, and devices having first trenches 320 of uniform depth (depth profile) exhibit uniform performance. Therefore, this etching process may be employed for device production, so long as first trenches 320 having a uniform depth are formed.

In all the aforementioned embodiments, a GaN substrate is employed as a growth substrate. However, the present invention is not limited thereto, and any substrate may be employed so long as it is made of a Group III nitride semiconductor. Although a C-plane substrate is employed in the aforementioned embodiments, the C-plane substrate may be replaced with, for example, an R-plane substrate, an M-plane substrate, or an A-plane substrate.

In Embodiments 1 to 3, the planarizing step employing CMP and the wet etching step are carried out after formation of semiconductor layers. However, the planarizing step employing CMP may be followed by formation of semiconductor layers, and subsequently followed by the wet etching step. Alternatively, semiconductor layers may be formed after the planarizing step employing CMP and the wet etching step. When the planarizing step is carried out before formation of semiconductor layers, as in the case of Embodiment 4, CMP may be replaced with dry etching and high-temperature thermal treatment for planarization. Similar to the cases of Embodiments 1 to 3, in Embodiment 4, the planarizing step employing CMP and the wet etching step may be carried out after formation of semiconductor layers.

The structure of a semiconductor layer or electrode formed on the top surface of a growth substrate is not limited to that described in the aforementioned embodiments, and there may be employed any of various structures which have hitherto been known as the structures of semiconductor layers or electrodes of light-emitting devices. For example, there may be employed a top-bottom electrode structure in which an n-electrode is formed on the bottom surface of a growth substrate.

In the aforementioned embodiments, the mask employed in the wet etching step is not removed. However, the mask may be removed after the wet etching step. Alternatively, the mask may be formed of a metal having high corrosion resistance (e.g., Pt or Ir), and the metal mask may be left as is and employed as an n-type electrode, to thereby produce a light-emitting device having a top-bottom electrode structure.

The etching pattern of the bottom surface of a growth substrate is not limited to that described in the aforementioned embodiments. No particular limitation is imposed on the etching pattern, so long as the etched growth substrate has a tapered surface. Light distribution may be controlled by the form of the processed bottom surface of the growth substrate; i.e., the pattern of a mask formed on the bottom surface of the growth substrate. Since the bottom surface of the growth substrate is processed to have a tapered form, a chip must be prevented from being inclined during wire bonding of a face-up-type light-emitting device. Therefore, the mask formed on the bottom surface of the growth substrate preferably has a pattern which allows the center of a pad to fall within an outwardly convex region defined by a closed curve, the region including the entire pattern of the mask and having the smallest possible area.

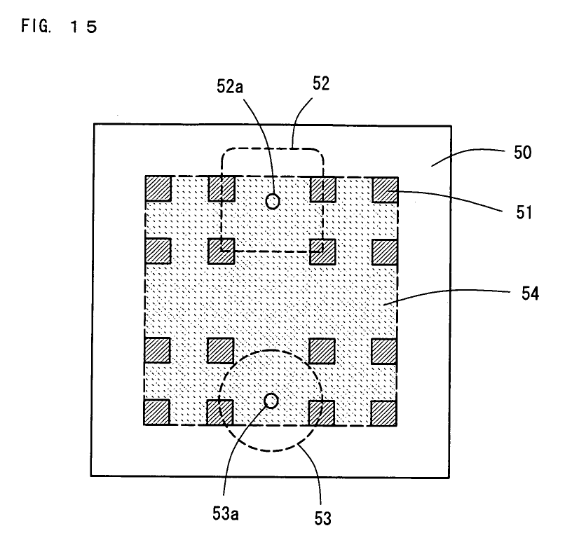

FIG. 15 shows an example of a mask pattern formed so that a chip is not inclined during wire bonding. This mask pattern corresponds to square masks 51 which are formed on the bottom surface of a GaN substrate 50 and are arranged in a 4×4 matrix form. Pad regions 52 and 53 respectively correspond to a round-cornered quadrangular portion defined by a dotted line and a circular portion defined by a dotted line, and the centers of the pad regions 52 and 53 correspond to pad center positions 52a and 53a, respectively. The shaded region shown in FIG. 15 is an outwardly convex region 54 which includes all the 16 square masks 51, which is defined by a closed curve, and which has the smallest possible area. The mask pattern allows the pad center positions 52a and 53a to fall within the region 54. Therefore, the mask pattern can prevent a chip from being inclined during wire bonding.

The light-emitting device of the present invention is applicable to, for example, a display apparatus or an illumination apparatus.

What is claimed is:

1. A method for producing a light-emitting device comprising a Group III nitride semiconductor growth substrate, and a Group III nitride semiconductor layer stacked on the top surface of the growth substrate, the method comprising:
planarizing the bottom surface of the growth substrate;
subsequently, forming a mask having a predetermined pattern on the bottom surface of the growth substrate; and
wet-etching the bottom surface of the growth substrate, to thereby form an embossment including a portion of the bottom surface of the growth substrate, the portion being a planar surface, and a tapered surface which extends from the periphery of the planar surface and are inclined with respect to the growth substrate.

2. A method for producing a light-emitting device according to claim 1, wherein the bottom surface of the growth substrate is planarized through chemical mechanical polishing.

3. A method for producing a light-emitting device according to claim 1, wherein wet etching is carried out to a depth of 5 μm or more as measured from the bottom surface of the growth substrate.

4. A method for producing a light-emitting device according to claim 1, wherein wet etching is carried out to a depth which is 40 to 70% of the thickness of the growth substrate.

5. A method for producing a light-emitting device according to claim 1, wherein the tapered surface is inclined by 20° to 70° with respect to the growth substrate.

6. A method for producing a light-emitting device according to claim 1, wherein the tapered surface is inclined by 60° with respect to the growth substrate.

7. A method for producing a light-emitting device according to claim 1, wherein wet etching is carried out by use of phosphoric acid.

8. A method for producing a light-emitting device according to claim 1, wherein the growth substrate is a C-plane substrate, and the bottom surface of the growth substrate is an N-polar surface.

9. A method for producing a light-emitting device according to claim 1, wherein the growth substrate is a GaN substrate.

10. A method for producing a light-emitting device according to claim 1, wherein the embossment comprises one or more protrusions.

11. A method for producing a light-emitting device according to claim 1, wherein the embossment comprises one dent provided at the center of the bottom surface of the growth substrate.

12. A method for producing a light-emitting device according to claim 1, wherein the embossment has a bottom surface which is parallel to the bottom surface of the growth substrate.

13. A method for producing a light-emitting device according to claim 1, wherein the embossment comprises a plurality of protrusions, and a first trench between adjacent protrusions is formed through wet etching which is allowed to proceed until etching eventually stops, so that the trench assumes a V-shape as viewed in cross section perpendicular to the bottom surface of the growth substrate.

14. A method for producing a light-emitting device according to claim 13, wherein the depth of first trenches is varied by modifying the size of a plurality of first openings provided in the mask for forming the first trenches.

15. A method for producing a light-emitting device according to claim 1, wherein the embossment comprises a plurality of protrusions; and both the first trench, which is provided between adjacent protrusions and assumes a V-shape as viewed in a cross section perpendicular to the bottom surface of the growth substrate, and a second trench which has a depth greater than that of the first trench and is employed for separating the light-emitting device into chips are formed through single-step wet etching via a first opening provided in the mask for forming the first trench and a second opening provided in the mask for forming the second trench, the second opening being greater in size than the first opening.

16. A method for producing a light-emitting device according to claim 15, wherein the first and second trenches are formed through wet etching which is allowed to proceed until etching eventually stops, so that the second trench assumes a V-shape as viewed in a cross section perpendicular to the bottom surface of the growth substrate.

17. A method for producing a light-emitting device according to claim 1, wherein the light-emitting device is of a face-up type, and the mask has a pattern which allows the center of a pad to fall within an outwardly convex region defined by a closed curve, the region including the entire pattern of the mask and having the smallest possible area.

18. A method for producing a light-emitting device according to claim 1, wherein the growth substrate has an absorption coefficient of 3/cm or less with respect to light emitted from the light-emitting device.

19. A light-emitting device comprising a Group III nitride semiconductor growth substrate, and a Group III nitride semiconductor layer stacked on the top surface of the growth substrate, wherein the growth substrate has an embossment including a portion of the bottom surface of the growth substrate, the portion being a planar surface, and a tapered surface which extends from the periphery of the planar surface and is inclined with respect to the growth substrate; and the tapered surface is formed through wet etching.

20. A light-emitting device according to claim 19, wherein the tapered surface is formed so as to attain a depth of 5 μm or more as measured from the bottom surface of the growth substrate.

21. A light-emitting device according to claim 19, wherein the tapered surface is formed so as to attain a depth which is 40 to 70% of the thickness of the growth substrate.

22. A light-emitting device according to claim 19, wherein the tapered surface is inclined by 20° to 70° with respect to the growth substrate.

23. A light-emitting device according to claim 19, wherein the tapered surface is inclined by 60° with respect to the growth substrate.

24. A light-emitting device according to claim 19, wherein the growth substrate is a GaN substrate.

25. A light-emitting device according to claim 19, wherein the growth substrate is a C-plane substrate, and the bottom surface of the growth substrate is an N-polar surface.

26. A light-emitting device according to claim 19, wherein the embossment comprises one or more protrusions.

27. A light-emitting device according to claim 19, wherein the embossment comprises one dent provided at the center of the bottom surface of the growth substrate.

28. A light-emitting device according to claim 19, wherein the embossment has a bottom surface which is parallel to the bottom surface of the growth substrate.

29. A light-emitting device according to claim 19, wherein the embossment comprises a plurality of protrusions, and a first trench formed between adjacent protrusions assumes a V-shape as viewed in a cross section perpendicular to the bottom surface of the growth substrate.

30. A light-emitting device according to claim 29, wherein a plurality of first trenches have different depths.

31. A light-emitting device according to claim 19, wherein the embossment comprises a plurality of protrusions, and includes a first trench which is formed between adjacent protrusions and assumes a V-shape as viewed in a cross section perpendicular to the bottom surface of the growth substrate, and a side surface of a second trench which has a depth greater than that of the first trench and is formed at a position at which the light-emitting device is separated into chips.

32. A light-emitting device according to claim 31, wherein the second trench assumes a V-shape as viewed in a cross section perpendicular to the bottom surface of the growth substrate.

33. A light-emitting device according to claim 19, wherein the light-emitting device is of a face-up type, and the mask has a pattern which allows the center of a pad to fall within an outwardly convex region defined by a closed curve, the region including the entire pattern of the mask and having the smallest possible area.

34. A light-emitting device according to claim 19, wherein the growth substrate has an absorption coefficient of 3/cm or less with respect to light emitted from the light-emitting device.
